(19) United States
(12) Patent Application Publication
(10) Pub. No.: US 2011/0253031 A1
(43) Pub. Date: Oct. 20, 2011

(54) PROCESS FOR PRODUCING SINGLE-CRYSTAL SAPPHIRE

(75) Inventor: Tomohiro Shonai, Ichihara-shi (JP)

(73) Assignee: SHOWA DENKO K.K., Minato-ku, Tokyo (JP)

(21) Appl. No.: 13/141,886

(22) PCT Filed: Dec. 16, 2009
(86) PCT No.: PCT/JP2009/070957

§ 371 Date: Jun. 23, 2011

(30) Foreign Application Priority Data
Dec. 24, 2008 (JP) 2008-327786

(51) Int. Cl. C30B 15/20

(52) U.S. Cl. 117/35

(57) ABSTRACT

Following steps are implemented: a melting step in which aluminum oxide within a crucible is melted to obtain an aluminum melt; a shoulder-portion formation step in which a seed crystal brought into contact with the aluminum melt is pulled up to thereby form a shoulder portion below the seed crystal; a body-portion formation step in which single-crystal sapphire is pulled up from the melt to form a body portion; and a tail-portion formation step in which a mixed gas including oxygen and an inert gas and having an oxygen concentration set at not less than 1.0 vol % nor more than 5.0 vol % is supplied while the single-crystal sapphire is pulled away from the melt to form a tail portion. Thus, when single-crystal sapphire is obtained by growth from a melt of aluminum oxide, formation of a protrusion in the tail portion of the single-crystal sapphire is more effectively inhibited.

### TECHNICAL FIELD

The present invention relates to a process for producing single-crystal sapphire using a melt of aluminum oxide.

### BACKGROUND ART

In recent years, single-crystal sapphire is widely used as a substrate material for growing an epitaxial film of a group III nitride semiconductor (such as GaN) on the occasion of producing blue LEDs, for example. Additionally, single-crystal sapphire is also widely used as a holding member or the like of a light polarizer used for a liquid-crystal projector, for example.

In general, a plate member, namely, a wafer of such single-crystal sapphire is obtained by cutting an ingot of single-crystal sapphire to have a predetermined thickness. Various methods to produce ingots of single-crystal sapphire have been proposed. However, a melting and solidifying method is often employed in the production, because this method provides favorable crystal characteristics and is likely to provide crystals having large diameters. In particular, the Czochralski method (Cz method), which is one of melting and solidifying methods is widely used for producing ingots of single-crystal sapphire.

To produce ingots of single-crystal sapphire by using the Czochralski method, a crucible is first filled with a material of aluminum oxide and is heated by using a high-frequency induction heating method or a resistance heating method, to thereby melt the material. After the material is melt, a seed crystal having been cut along a predetermined crystal orientation is brought into contact with the surface of the melt of the material. The seed crystal is pulled upward at a predetermined speed while being rotated at a predetermined rotation speed, to thereby grow a single crystal (see Patent Document 1, for example).

It is also known that when a raw material for crystals is heated and melted, after pressure in a furnace body is reduced to the order enough to remove a gas generated from the raw material for crystals by heating, the raw material for crystals is made to be gradually melted while the gas is removed, and the pressure in the furnace body is returned to the atmospheric pressure under sufficient partial pressure of oxygen by successively introducing a mixed gas made of oxygen and any one of nitrogen and an inert gas, and thereafter, a growing crystal is pulled up (see Patent Document 2, for example).
Patent Document 1: Japanese Patent Application Laid-Open Publication No. 2008-207993
Patent Document 2: Japanese Patent Application Laid-Open Publication No. 2007-246320

### DISCLOSURE OF THE INVENTION

### Problems to be Solved by the Invention

When ingots of single-crystal sapphire are produced by using the Czochralski method, the tip portion of an ingot (referred to as a tail portion) that is in contact with a melt of the raw material in the production of the ingots may have a protrudent shape. If the tail portion of an ingot has such a protrudent shape, when the amount of melt in the crucible is decreased along with growth of the ingot, the tip of the tail portion is brought into contact with the bottom of the crucible and this prevents further crystal growth. Since the protrusion formed in this manner is not used as a wafer, the effective length of the ingot usable when a wafer is cut out becomes shorter, which leads to a decrease in yield.

Meanwhile, when ingots of single-crystal sapphire are produced by using the Czochralski method, the tail portion of an ingot that is in contact with the melt of the raw material in the crucible is pulled away from the melt of the raw material after the ingots are grown. At this time, if separation of the ingot from the melt of the raw material is incomplete, aluminum oxide adheres in a solid state so as to trail behind the tail portion of the ingot and thus the protrusion formed on the tail portion becomes further longer. Occurrence of such a phenomenon leads to a further decrease in yield.

To deal with this problem, the above-mentioned Patent Document 2 proposes that the raw material of aluminum oxide filled in the crucible be heated under reduced pressure until the raw material is melted and single-crystal sapphire be grown from the melt of the raw material in an atmosphere having normal pressure with partial pressure of oxygen set at 10 to 500 Pa after the raw material is melted. However, it is insufficient to inhibit a protrusion from being formed in the tail portion of an ingot even when ingots of single-crystal sapphire are produced under the condition described in the Patent Document 2.

An object of the present invention is to inhibit formation of a protrusion in the tail portion of single-crystal sapphire more effectively, when the single-crystal sapphire is obtained by growth from a melt of aluminum oxide.

### Means for Solving the Problems

In order to attain the above object, a process for producing single-crystal sapphire to which the present invention is applied includes the steps of: melting aluminum oxide within a crucible placed in a chamber to obtain a melt of the aluminum oxide; growing single-crystal sapphire by pulling up the single-crystal sapphire from the melt while the chamber is supplied with a first mixed gas having an oxygen concentration set at a first concentration; and separating the single-crystal sapphire from the melt by further pulling up the single-crystal sapphire to pull away from the melt while the chamber is supplied with a second mixed gas having an oxygen concentration set at a second concentration that is higher than the first concentration.

In such a process for producing single-crystal sapphire, the first mixed gas and the second mixed gas may be made by mixing an inert gas and oxygen.

The second concentration of the second mixed gas in the step of separating may be set at not less than 1.0 vol % nor more than 5.0 vol %. Note that in this description, a volume concentration of a gas may be simply denoted as “%.”

Additionally, the first concentration of the first mixed gas in the step of growing may be set at not less than 0.6 vol % nor more than 3.0 vol %.

In the step of growing, the single-crystal sapphire may be grown in a c-axis direction thereof.

In another aspect, a process for producing single-crystal sapphire to which the present invention is applied includes the steps of: growing single-crystal sapphire by pulling up the single-crystal sapphire from a melt of aluminum oxide within a crucible placed in a chamber; and separating the single-crystal sapphire from the melt by further pulling up the single-crystal sapphire to pull away from the melt while the chamber is supplied with a mixed gas including oxygen and an inert gas, the oxygen having a concentration set at not less than 1.0 vol % nor more than 5.0 vol %.

In such a process for producing single-crystal sapphire, the concentration of the oxygen in the mixed gas in the step of separating may be set at not less than 3.0 vol % nor more than 5.0 vol %.

In the step of growing, the single-crystal sapphire may be grown in a c-axis direction thereof.

In a further aspect, the present invention is a process for producing single-crystal sapphire including pulling up single-crystal sapphire from a melt of aluminum oxide within a crucible, the process including the steps of: growing the single-crystal sapphire by pulling up the single-crystal sapphire from the melt in an atmosphere having an oxygen concentration set at a first concentration; and separating the single-crystal sapphire from the melt by further pulling up the single-crystal sapphire to pull away from the melt in an atmosphere having an oxygen concentration set at a second concentration that is higher than the first concentration.

In such a process for producing single-crystal sapphire, the second concentration in the step of separating may be set at not less than 1.0 vol % nor more than 5.0 vol %.

The first concentration in the step of growing may be set at not less than 0.6 vol % nor more than 3.0 vol %.

### Advantages of the Invention

According to the present invention, it is possible to inhibit formation of a protrusion in the tail portion of single-crystal sapphire more effectively, when the single-crystal sapphire is obtained by growth from a melt of aluminum oxide.

### BEST MODES FOR CARRYING OUT THE INVENTION

Hereinafter, an exemplary embodiment of the present invention will be described in detail with reference to the accompanying drawings.

FIG. 1 is a diagram for illustrating a configuration of a single crystal pulling apparatus 1 to which the present exemplary embodiment is applied.

The single crystal pulling apparatus 1 includes a furnace 10 for growing a sapphire ingot 200 formed of single-crystal sapphire. The furnace 10 includes a heat insulated container 11. The heat insulated container 11 has a cylindrical outer shape, and has a cylindrical space formed therein. The heat insulated container 11 is composed by assembling components formed of a heat insulating material made of zirconia. The furnace 10 further includes a chamber 14 containing the heat insulated container 11 in the space inside thereof. Furthermore, the furnace 10 includes: a gas supply pipe 12 that is formed to penetrate a side surface of the chamber 14 and supplies a gas to the inside of the heat insulated container 11 from the outside of the chamber 14 through the chamber 14; and a gas exhaust pipe 13 that is also formed to penetrate a side surface of the chamber 14 and exhausts the gas from the inside of the heat insulated container 11 toward outside through the chamber 14.

Additionally, at a lower portion inside of the heat insulated container 11, a crucible 20 containing an aluminum melt 300 made by melting aluminum oxide is arranged so as to open vertically upward. The crucible 20 is composed of iridium, and has a circular bottom. The crucible 20 has a diameter, a height and a thickness of 150 mm, 200 mm and 2 mm, respectively.

The furnace 10 further includes a metallic heating coil 30 wound around a portion that is located outside of the side surface of a lower portion of the heat insulated container 11 and inside of the side surface of a lower portion of the chamber 14. The heating coil 30 is arranged so as to face a wall surface of the crucible 20 with the heat insulated container 11 interposed in between. The lower edge of the heating coil 30 is located lower than the lower edge of the crucible 20, while the upper edge of the heating coil 30 is located higher than the upper edge of the crucible 20.

Furthermore, the furnace 10 includes a pulling bar 40 extending downward from above through through-holes respectively provided in top surfaces of the heat insulated container 11 and the chamber 14. The pulling bar 40 is attached so as to be movable in a vertical direction and rotatable around an axis. Note that an unillustrated sealing member is provided between the through-hole provided in the chamber 14 and the pulling bar 40. Additionally, a holding member 41 for mounting and holding a seed crystal 210 (see FIG. 2 to be described later) being a material for growing the sapphire ingot 200 is attached to the vertically lower end of the pulling bar 40.

Additionally, the single crystal pulling apparatus 1 includes: a pulling drive unit 50 for pulling the pulling bar 40 vertically upward; and a rotation drive unit 60 for rotating the pulling bar 40. The pulling drive unit 50 is configured with a motor and the like so as to be capable of adjusting a pulling speed of the pulling bar 40. The rotation drive unit 60 is also configured with a motor and the like so as to be capable of adjusting a rotation speed of the pulling bar 40.

Furthermore, the single crystal pulling apparatus 1 includes a gas supply unit 70 to supply a gas to the inside of the chamber 14 through the gas supply pipe 12. In the present exemplary embodiment, the gas supply unit 70 supplies a mixed gas that is a mixture of oxygen supplied from an O₂ source 71 and nitrogen, which is an example of an inert gas, supplied from an N₂ source 72. The gas supply unit 70 is capable of adjusting the concentration of the oxygen in the mixed gas by making a mixture ratio of the oxygen and the nitrogen being variable, and is also capable of adjusting a flow rate of the mixed gas supplied to the inside of the chamber 14.

Meanwhile, the single crystal pulling apparatus 1 includes an exhaust unit 80 to exhaust the gas from the inside of the chamber 14 through the gas exhaust pipe 13. The exhaust unit 80 includes a vacuum pump and the like, for example, and is capable of decompressing the chamber 14 and exhausting the gas supplied from the gas supply unit 70.

Furthermore, the single crystal pulling apparatus 1 includes a coil power supply 90 to supply a current to the heating coil 30. The coil power supply 90 is capable of setting whether or not a current is supplied to the heating coil 30 and the amount of a current to be supplied.

Additionally, the single crystal pulling apparatus 1 includes a weight detection unit 110 to detect the weight of the sapphire ingot 200 growing at the lower side of the pulling bar 40 by use of the pulling bar 40. The weight detection unit 110 is configured with a known weight sensor and the like, for example.

Additionally, the single crystal pulling apparatus 1 includes a controller 100 to control operations of the pulling drive unit 50, the rotation drive unit 60, the gas supply unit 70, the exhaust unit 80 and the coil power supply 90 described above. The controller 100 calculates the diameter of a crystal of the pulled-up sapphire ingot 200 based on a weight signal outputted from the weight detection unit 110, and feeds the diameter back to the coil power supply 90.

FIG. 2 is a diagram illustrating an example of a structure of the sapphire ingot 200 produced by using the single crystal pulling apparatus 1 shown in FIG. 1.

The sapphire ingot 200 includes: the seed crystal 210 being a material for growing the sapphire ingot 200; a shoulder portion 220 that extends to a lower portion of the seed crystal 210 and is integral with the seed crystal 210; a body portion 230 that extends to a lower portion of the shoulder portion 220 and is integral with the shoulder portion 220; and a tail portion 240 that extends to a lower portion of the body portion 230 and is integral with the body portion 230. The sapphire ingot 200 has single-crystal sapphire growing in the c-axis direction from the upper side, namely, from the side of the seed crystal 210 to the lower side, namely, to the side of the tail portion 240.

The shoulder portion 220 is shaped so that the diameter thereof gradually increases from the side of the seed crystal 210 toward the side of the body portion 230. The body portion 230 is shaped so as to have substantially the same diameter from the upper side to the lower side. Note that the diameter of the body portion 230 is set to a value slightly larger than that of a desired wafer of single-crystal sapphire. The tail portion 240 is shaped so that the diameter thereof gradually decreases from the upper side to the lower side and is thus convex from the upper side to the lower side.

FIG. 3 is a flowchart for illustrating a procedure to produce the sapphire ingot 200 shown in FIG. 2 by using the single crystal pulling apparatus 1 shown in FIG. 1.

On the occasion of producing the sapphire ingot 200, a melting step is first carried out in which solid aluminum oxide filled in the crucible 20 in the chamber 14 is melted with heat (Step 101).

Next, a seeding step is carried out in which the temperature is adjusted with the lower edge of the seed crystal 210 brought into contact with a melt of the aluminum oxide, namely, the aluminum melt 300 (Step 102).

Next, a shoulder-portion formation step is carried out in which the seed crystal 210 brought into contact with the aluminum melt 300 is pulled upward while the seed crystal 210 is rotated, to thereby form the shoulder portion 220 below the seed crystal 210 (Step 103).

Subsequently, a body-portion formation step, which is an example of a growth step, is carried out in which the shoulder portion 220 is pulled upward through the seed crystal 210 while the shoulder portion 220 is rotated, thereby forming the body portion 230 below the shoulder portion 220 (Step 104).

Further subsequently, a tail-portion formation step is carried out in which the body portion 230 is pulled upward through the seed crystal 210 and the shoulder portion 220 while the body portion 230 is rotated, to pull away from the aluminum melt 300, thereby forming the tail portion 240 below the body portion 230 (Step 105).

Then, after the obtained sapphire ingot 200 is cooled, the sapphire ingot 200 is taken outside of the chamber 14, and a series of production steps is completed.

Note that the sapphire ingot 200 obtained in this manner is first cut at the boundary between the shoulder portion 220 and the body portion 230 and at the boundary between the body portion 230 and the tail portion 240, to cut out the body portion 230. Next, the cut-out body portion 230 is further cut in a direction orthogonal to the longitudinal direction thereof, to provide a wafer of single-crystal sapphire. At this time, since the sapphire ingot 200 of the present exemplary embodiment has a crystal growing in the c-axis direction thereof, the principal plane of the obtained wafer is the c-plane ((0001) plane). The obtained wafer is then used for production of a blue LED, a light polarizer, and the like.

Now, the above-mentioned steps are specifically described. Here, a description is given in sequence starting with a preparation step carried out prior to the melting step in Step 101.

### (Preparation Step)

In the preparation step, a <0001> c-axis seed crystal 210 is first prepared. Next, the seed crystal 210 is attached to the holding member 41 of the pulling bar 40, and is set at a predetermined position. Subsequently, the crucible 20 is filled with a raw material of aluminum oxide. The heat insulated container 11 is assembled in the chamber 14 by using components formed of a heat insulating material made of zirconia.

The chamber 14 is then decompressed by using the exhaust unit 80 with no gas supplied from the gas supply unit 70. After that, the gas supply unit 70 supplies the chamber 14 with nitrogen by using the N₂ source 72, to thereby make the inside of the chamber 14 have normal atmospheric pressure. Accordingly, when the preparation step is completed, the inside of the chamber 14 is set to have an extremely high nitrogen concentration and an extremely low oxygen concentration.

### (Melting Step)

In the melting step, the gas supply unit 70 subsequently supplies the chamber 14 with nitrogen by using the N₂ source 72 at a flow rate of 5 l/min. At this time, the rotation drive unit 60 rotates the pulling bar 40 at a first rotation speed.

Additionally, the coil power supply 90 supplies the heating coil 30 with a high-frequency alternating current (in the following description, referred to as high-frequency current). When a high-frequency current is supplied from the coil power supply 90 to the heating coil 30, a magnetic flux repeatedly appears and disappears around the heating coil 30. When the magnetic flux generated in the heating coil 30 traverses the crucible 20 through the heat insulated container 11, a magnetic field that hinders a change of the magnetic field traversing the crucible 20 is generated on the wall surface of the crucible 20, to thereby generate an eddy current in the crucible 20. Then, in the crucible 20, the eddy current (I) generates Joule heat (W=I²R) in proportion to the skin resistance (R) of the crucible 20, to thereby heat the crucible 20. When the crucible 20 is heated and thereby the aluminum oxide contained in the crucible 20 is heated to more than the melting point thereof (2054 degrees C.), the aluminum oxide is melted in the crucible 20 to provide the aluminum melt 300.

### (Seeding Step)

In the seeding step, the gas supply unit 70 supplies the chamber 14 with a mixed gas having nitrogen and oxygen mixed at a predetermined ratio by using the O₂ source 71 and the N₂ source 72. However, in the seeding step, a mixed gas of oxygen and nitrogen does not necessarily have to be supplied, as described later. For example, only nitrogen may be supplied.

Additionally, the pulling drive unit 50 lowers the pulling bar 40 to a position where the lower edge of the seed crystal 210 attached to the holding member 41 is brought into contact with the aluminum melt 300 in the crucible 20, and stops the pulling bar 40 there. In this state, the coil power supply 90 adjusts the high-frequency current supplied to the heating coil 30 on the basis of a weight signal from the weight detection unit 110.

### (Shoulder-Portion Formation Step)

In the shoulder-portion formation step, after the coil power supply 90 adjusts the high-frequency current supplied to the heating coil 30, the pulling bar 40 is held for a while until the temperature of the aluminum melt 300 is stabilized. After that, the pulling bar 40 is pulled up at a first pulling speed while being rotated at the first rotation speed.

Then, the seed crystal 210 is pulled up while being rotated with the lower edge thereof soaked in the aluminum melt 300. At the lower edge of the seed crystal 210, the shoulder portion 220 spreading vertically downward is formed.

Note that the shoulder-portion formation step is completed when the diameter of the shoulder portion 220 becomes larger than that of a desired wafer by about several millimeters.

### (Body-Portion Formation Step)

In the body-portion formation step, the gas supply unit 70 mixes nitrogen and oxygen at a predetermined ratio by using the O₂ source 71 and the N₂ source 72, and supplies the chamber 14 with the mixed gas having the oxygen concentration set in a range of not less than 0.6 vol % nor more than 3.0 vol %.

Meanwhile, the coil power supply 90 subsequently supplies the heating coil 30 with a high-frequency current, and heats the aluminum melt 300 through the crucible 20.

Additionally, the pulling drive unit 50 pulls up the pulling bar 40 at a second pulling speed. The second pulling speed may be the same as the first pulling speed in the shoulder-portion formation step, or may be different from the first pulling speed.

Furthermore, the rotation drive unit 60 rotates the pulling bar 40 at a second rotation speed. The second rotation speed may be the same as the first rotation speed in the shoulder-portion formation step, or may be different from the first rotation speed.

Since the shoulder portion 220 integrated with the seed crystal 210 is pulled up while the shoulder portion 220 is rotated with the lower edge thereof soaked in the aluminum melt 300, the body portion 230, which is preferably cylindrical, is formed at the lower edge of the shoulder portion 220. It is only necessary that the body portion 230 is a body having a diameter not less than the diameter of a desired wafer.

### (Tail-Portion Formation Step)

In the tail-portion formation step, the gas supply unit 70 supplies the chamber 14 with a mixed gas having nitrogen and oxygen mixed at a predetermined ratio by using the O₂ source 71 and the N₂ source 72. From the viewpoint of inhibiting the crucible 20 from deteriorating due to oxidation, it is preferable that the concentration of the oxygen in the mixed gas in the tail-portion formation step be nearly equal to or lower than that in the body-portion formation step. However, from the viewpoint of reducing the length H (see FIG. 2) in the vertical direction of the tail portion 240 in the sapphire ingot 200 to be obtained so as to improve productivity, it is preferable that the concentration of the oxygen in the mixed gas in the tail-portion formation step be higher than that in the body-portion formation step.

Meanwhile, the coil power supply 90 subsequently supplies the heating coil 30 with a high-frequency current, and heats the aluminum melt 300 through the crucible 20.

Additionally, the pulling drive unit 50 pulls up the pulling bar 40 at a third pulling speed. The third pulling speed may be the same as the first pulling speed in the shoulder-portion formation step or the second pulling speed in the body-portion formation step, or may be different from these speeds.

Furthermore, the rotation drive unit 60 rotates the pulling bar 40 at a third rotation speed. The third rotation speed may be the same as the first rotation speed in the shoulder-portion formation step or the second rotation speed in the body-portion formation step, or may be different from these speeds.

Note that in an early stage of the tail-portion formation step, the lower edge of the tail portion 240 is kept in contact with the aluminum melt 300.

Then, in a last stage of the tail-portion formation step after a lapse of predetermined time, the pulling drive unit 50 increases the pulling speed of the pulling bar 40 to pull the pulling bar 40 further upward, thereby pulling the lower edge of the tail portion 240 away from the aluminum melt 300. Then, the sapphire ingot 200 shown in FIG. 2 is obtained.

In the present exemplary embodiment, the chamber 14 is supplied with a mixed gas having the oxygen concentration set at not less than 1.0 vol % nor more than 5.0 vol % in the tail-portion formation step. Setting the concentration of the oxygen included in the mixed gas in the tail-portion formation step to 1.0 vol % or more may reduce the length H (see FIG. 2) in the vertical direction of the tail portion 240 in the sapphire ingot 200 to be obtained, as compared with a case where the oxygen concentration is set to less than 1.0 vol %. As a result, a period up to when the tail portion 240 is brought into contact with the bottom of the crucible 20 may be made longer and more sapphire ingots 200 having the body portions 230 may be obtained from the same amount of the aluminum melt 300, as compared with a conventional production method. Additionally, setting the concentration of the oxygen included in the mixed gas in the tail-portion formation step to 5.0 vol % or less inhibits the crucible 20 made of iridium from deteriorating due to oxidation and may make the service life of the crucible 20 longer, as compared with a case where the oxygen concentration in the mixed gas is set to more than 5.0 vol %.

In the present exemplary embodiment, the chamber 14 is supplied with a mixed gas having the oxygen concentration set at not less than 0.6 vol % nor more than 3.0 vol % in the body-portion formation step. Setting the concentration of the oxygen included in the mixed gas in the body-portion formation step to 0.6 vol % or more inhibits air bubbles from being taken into the single-crystal sapphire forming the body portion 230 and may inhibit generation of defects of air bubbles in the body portion 230, as compared with a case where the oxygen concentration is set to less than 0.6 vol %. In particular, in the present exemplary embodiment, it is possible to inhibit generation of defects of air bubbles even when the body portion 230 is formed by crystal growth in the c-axis direction, although it is known that crystal growth in the c-axis direction is likely to cause air bubbles to be taken inside and thus is likely to generate defects of air bubbles as compared with crystal growth in the a-axis direction. Additionally, setting the concentration of the oxygen included in the mixed gas in the body-portion formation step to 3.0 vol % or less inhibits the crucible 20 made of iridium from deteriorating due to oxidation and may make the service life of the crucible 20 longer, as compared with a case where the oxygen concentration in the mixed gas is set to more than 3.0 vol %.

Additionally, in the present exemplary embodiment, if the heat insulated container 11 is supplied with the mixed gas having the oxygen concentration set in the range of not less than 0.6 vol % nor more than 3.0 vol % in the shoulder-portion formation step, it is possible to inhibit generation of defects of air bubbles in the shoulder portion 220. This makes crystallinity of the body portion 230 further formed below the shoulder portion 220 more favorable.

In the present exemplary embodiment, a mixed gas that is a mixture of oxygen and nitrogen is used; however, the mixed gas is not limited thereto. For example, a mixed gas of oxygen and argon, which is an example of an inert gas, may be used.

Meanwhile, the crucible 20 is heated by using a so-called electromagnetic induction heating method in the present exemplary embodiment; however, the heating method is not limited thereto. For example, a resistance heating method may be employed.

### EXAMPLES

Next, a description is given of examples of the present invention. However, the present invention is not limited to the examples.

The inventor produced sapphire ingots 200 by using the single crystal pulling apparatus 1 shown in FIG. 1 with various production conditions in the growth step of single-crystal sapphire being varied, here particularly with the oxygen concentration in the mixed gas supplied to the chamber 14 in the tail-portion formation step being varied. The inventor then examined the states of the lengths H in the vertical direction of tail portions 240 in the obtained sapphire ingots 200, the states of deterioration of the used crucible 20 and the states of defects of air bubbles generated in body portions 230 of 4-inch crystals.

FIG. 4 shows a relationship between the various production conditions and the evaluation results in examples 1 to 9 and comparative examples 1 to 3.

As the production conditions, FIG. 4 lists: the rotation speed of the pulling bar 40 (corresponding to the first rotation speed), the pulling speed of the pulling bar 40 (corresponding to the first pulling speed) and the oxygen concentration in the mixed gas supplied to the chamber 14 in the shoulder-portion formation step; the rotation speed of the pulling bar 40 (corresponding to the second rotation speed), the pulling speed of the pulling bar 40 (corresponding to the second pulling speed) and the oxygen concentration in the mixed gas supplied to the chamber 14 in the body-portion formation step; and the rotation speed of the pulling bar 40 (corresponding to the third rotation speed), the pulling speed of the pulling bar 40 (corresponding to the third pulling speed) and the oxygen concentration in the mixed gas supplied to the chamber 14 in the tail-portion formation step.

Additionally, as evaluation items, FIG. 4 shows the states of the lengths H in the vertical direction of the tail portions 240 (tail-portion lengths) with 4 ranks of A to D, the states of deterioration of the crucible 20 after the sapphire ingots 200 are produced with 4 ranks of A to D, and the states of defects of air bubbles existing in the body portions 230 with 4 ranks of A to D. The evaluation “A,” “B,” “C” and “D” indicate “good,” “slightly good,” “slightly poor” and “poor,” respectively.

As for the lengths H in the vertical direction of the tail portions 240, “A” represents a case where the length of a protrusion toward the melt is less than 20 mm while the diameter of the ingot is 4 inches, “B” represents a case where the length is not less than 20 mm and less than 40 mm, “C” represents a case where the length is not less than 40 mm and less than 60 mm, and “D” represents a case where the length is not less than 60 mm.

As for deterioration of the crucible 20, evaluation was made with the rate of change of weight decrease (wt %) of the crucible 20 before and after use. “A” represents a case of “less than 0.01 wt %,” “B” represents a case of “not less than 0.01 wt % and less than 0.03 wt %,” “C” represents a case of “not less than 0.03 wt % and less than 0.08 wt %,” and “D” represents a case of “not less than 0.08 wt %.”

Additionally, as for defects of air bubbles in the body portions 230, “A” represents a case of “no air bubbles (transparent),” “B” represents a case of “air bubbles exist locally,” “C” represents a case of “the whole area has air bubbles but transparent portions (with no air bubbles) exist partially,” and “D” represents a case of “the whole area has air bubbles and is whitish (air bubbles exist).”

In all the examples 1 to 9, the oxygen concentration in the mixed gas supplied to the chamber 14 in the tail-portion formation step is set at not less than 1.0 vol % nor more than 5.0 vol %, and the evaluation results of the tail-portion lengths are “A” or “B.” In particular, when the oxygen concentration in the mixed gas is in the range of not less than 3.0 vol % nor more than 5.0 vol %, all the evaluation results of the tail-portion lengths are “A.” The reason is considered as follows: when the oxygen concentration in the mixed gas supplied to the chamber 14 is increased, some of the oxygen is taken into the aluminum melt 300 in the crucible 20 or separation of oxygen from the aluminum melt 300 in the crucible 20 is inhibited, to thereby decrease viscosity of the aluminum melt 300 in the tail-portion formation step more than ever before, causing the aluminum melt 300 to easily separate from the tail portion 240.

Meanwhile, in the examples 1 to 6, 8 and 9 among the examples 1 to 9, the evaluation results of deterioration of the crucible 20 are “A” or “B.” Note that in the example 7, the evaluation result of deterioration of the crucible 20 is “C”; however, this may be attributed to promotion of oxidation of the crucible 20 in the body-portion formation step, which is performed for a longer time than the tail-portion formation step, in consideration of the oxygen concentration in the mixed gas in the body-portion formation step having an extremely large value of 4.0 vol %.

Furthermore, in the examples 1 to 6, 8 and 9 among the examples 1 to 9, the oxygen concentration in the mixed gas supplied to the chamber 14 in the body-portion formation step is set at not less than 0.6 vol % nor more than 3.0 vol %, and the evaluation results of defects of air bubbles are “A” or “B.” In particular, when the oxygen concentration in the mixed gas is in the range of not less than 1.5 vol % nor more than 3.0 vol %, all the evaluation results of defects of air bubbles are “A.” The reason is considered as follows: when the oxygen concentration in the mixed gas supplied to the chamber 14 is increased, some of the oxygen is taken into the aluminum melt 300 in the crucible 20 or separation of oxygen from the aluminum melt 300 in the crucible 20 is inhibited, to thereby decrease viscosity of the aluminum melt 300 in the body-portion formation step more than ever before, resulting in preventing air bubbles from being taken into the single crystals.

On the other hand, in the comparative example 1 among the comparative examples 1 to 3, the oxygen concentration in the mixed gas supplied to the chamber 14 in the tail-portion formation step has a small value of 0.5 vol %, and the evaluation result of the tail-portion lengths is “D.” In the comparative examples 2 and 3, the oxygen concentration in the mixed gas supplied to the chamber 14 in the tail-portion formation step has a large value of 6.0 vol %, and the evaluation results of defects of air bubbles are “A” or “B.”

Additionally, although the evaluation result of deterioration of the crucible 20 in the comparative example 1 is “A,” the evaluation results of deterioration of the crucible 20 in the comparative examples 2 and 3 are “D.” This may be attributed to promotion of oxidation of the crucible 20 in the tail-portion formation step, since the oxygen concentration in the mixed gas in the tail-portion formation step is high.

Furthermore, in the comparative example 1 among the comparative examples 1 to 3, the oxygen concentration in the mixed gas supplied to the chamber 14 in the body-portion formation step has a small value of 0.5 vol %, and the evaluation result of defects of air bubbles is “D.” Furthermore, in the comparative examples 2, since the oxygen concentration in the mixed gas supplied to the chamber 14 in the body-portion formation step is 3.0 vol %, the evaluation result of defects of air bubbles is “A.” In the comparative examples 3, the oxygen concentration in the mixed gas supplied to the chamber 14 in the body-portion formation step has a large value of 4.0 vol %, and the evaluation results of defects of air bubbles are “B.”

Accordingly, the comparative example 1 is effective for deterioration of the crucible 20, but is insufficient for reduction of the tail-portion length and generation of defects of air bubbles. Meanwhile, the comparative examples 2 and 3 are effective for reduction of the tail-portion length and generation of defects of air bubbles, but are insufficient for deterioration of the crucible 20.

As has been described above, it is understood that setting the oxygen concentration in the mixed gas supplied to the chamber 14 at not less than 1.0 vol % nor more than 5.0 vol %, more preferably not less than 3.0 vol % nor more than 5.0 vol %, in the tail-portion formation step for forming the tail portion 240 of the sapphire ingot 200 leads to reduction of the length H in the vertical direction of the tail portion 240 in the obtained sapphire ingot 200 and inhibition of deterioration of the crucible 20.

### BRIEF DESCRIPTION OF THE DRAWINGS

FIG. 1 is a diagram for illustrating a configuration of a single crystal pulling apparatus to which the exemplary embodiment is applied;

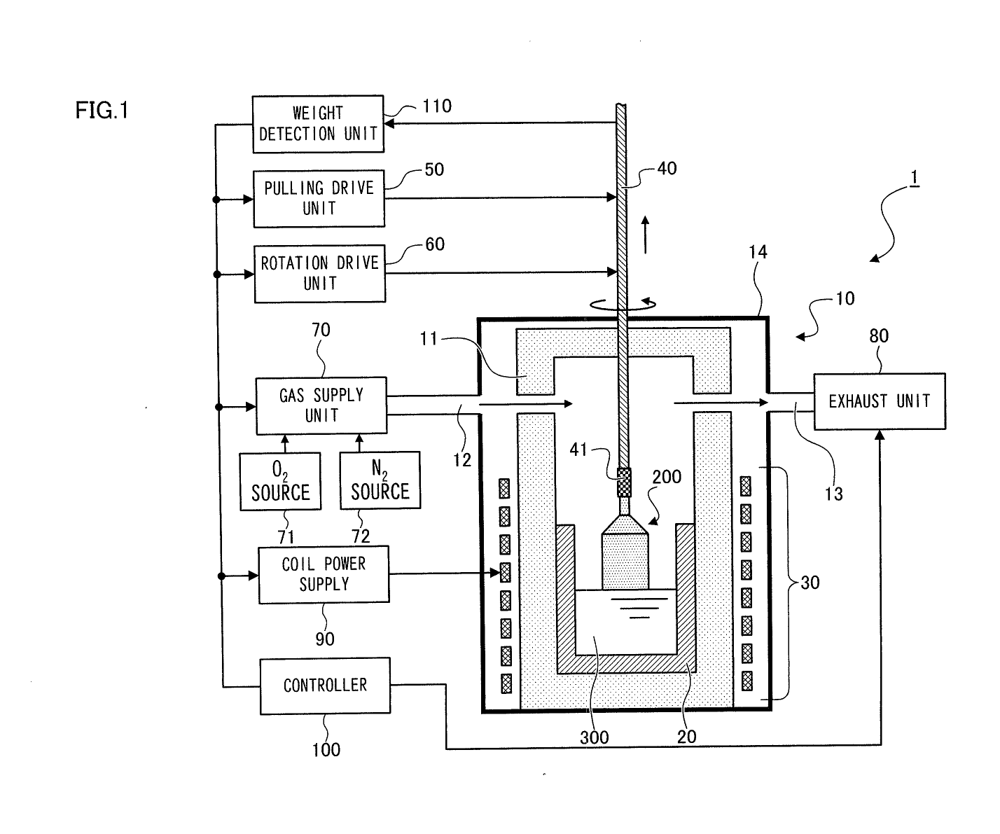

FIG. 2 is a diagram illustrating an example of a structure of the sapphire ingot obtained by using the single crystal pulling apparatus;

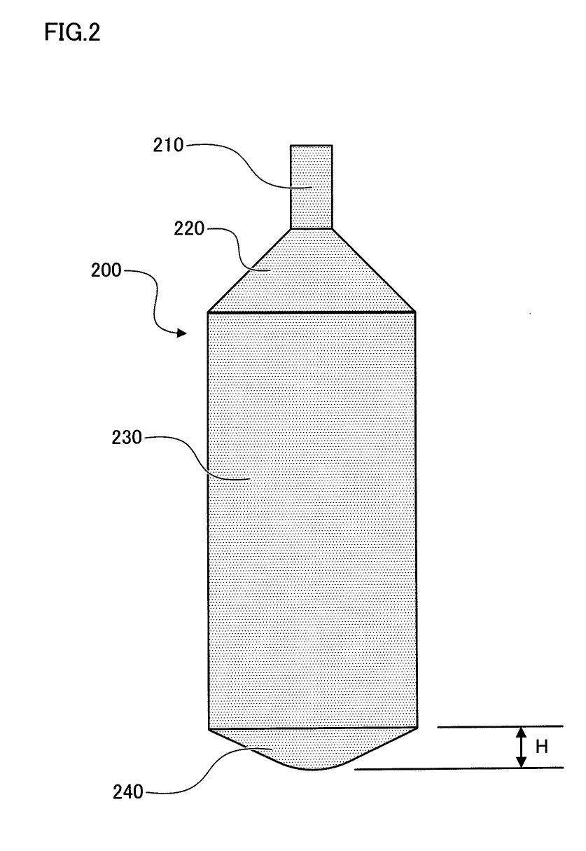

FIG. 3 is a flowchart for illustrating a procedure to produce the sapphire ingot by using the single crystal pulling apparatus; and

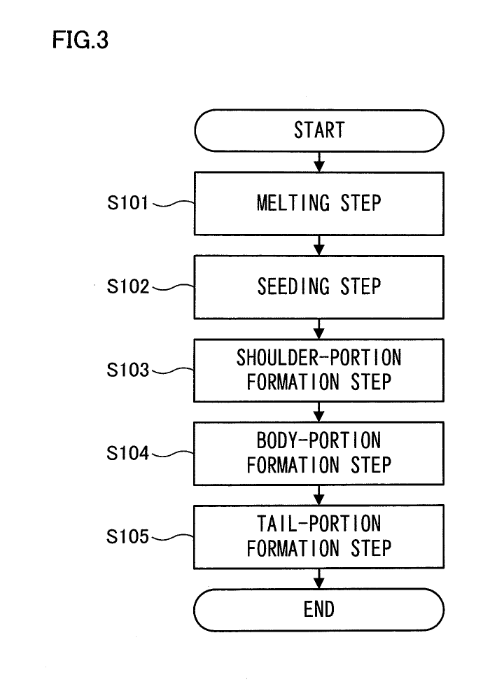

FIG. 4 is a table showing the production conditions and the evaluation results of the sapphire ingots in the examples and the comparative examples.

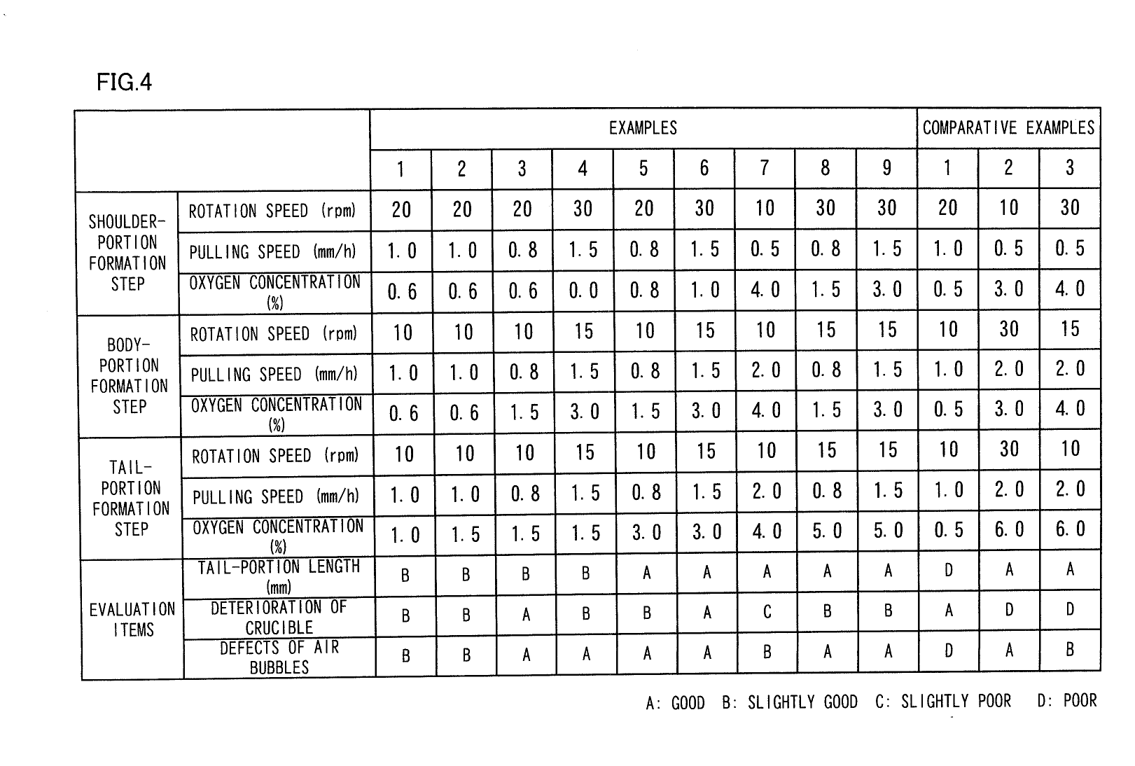

### DESCRIPTION OF REFERENCE NUMERALS AND SIGNS

1 . . . single crystal pulling apparatus
10 . . . furnace
11 . . . heat insulated container
12 . . . gas supply pipe
13 . . . gas exhaust pipe
14 . . . chamber
20 . . . crucible
30 . . . heating coil
40 . . . pulling bar
41 . . . holding member
50 . . . pulling drive unit
60 . . . rotation drive unit
70 . . . gas supply unit
71 . . . O₂ source
72 . . . N₂ source
80 . . . exhaust unit
90 . . . coil power supply
100 . . . controller
110 . . . weight detection unit
200 . . . sapphire ingot
210 . . . seed crystal
220 . . . shoulder portion
230 . . . body portion
240 . . . tail portion
300 . . . aluminum melt

1. A process for producing single-crystal sapphire, comprising the steps of:
melting aluminum oxide within a crucible placed in a chamber to obtain a melt of the aluminum oxide;
growing single-crystal sapphire by pulling up the single-crystal sapphire from the melt while the chamber is supplied with a first mixed gas having an oxygen concentration set at a first concentration; and
separating the single-crystal sapphire from the melt by further pulling up the single-crystal sapphire to pull away from the melt while the chamber is supplied with a second mixed gas having an oxygen concentration set at a second concentration that is higher than the first concentration.

2. The process for producing single-crystal sapphire according to claim 1, wherein the first mixed gas and the second mixed gas are made by mixing an inert gas and oxygen.

3. The process for producing single-crystal sapphire according to claim 1, wherein the second concentration of the second mixed gas in the step of separating is set at not less than 1.0 vol % nor more than 5.0 vol %.

4. The process for producing single-crystal sapphire according to claim 1, wherein the first concentration of the first mixed gas in the step of growing is set at not less than 0.6 vol % nor more than 3.0 vol %.

5. The process for producing single-crystal sapphire according to claim 1, wherein in the step of growing, the single-crystal sapphire is grown in a c-axis direction thereof.

6. A process for producing single-crystal sapphire, comprising the steps of:
growing single-crystal sapphire by pulling up the single-crystal sapphire from a melt of aluminum oxide within a crucible placed in a chamber; and
separating the single-crystal sapphire from the melt by further pulling up the single-crystal sapphire to pull away from the melt while the chamber is supplied with a mixed gas including oxygen and an inert gas, the oxygen having a concentration set at not less than 1.0 vol % nor more than 5.0 vol %.

7. The process for producing single-crystal sapphire according to claim 6, wherein the concentration of the oxygen in the mixed gas in the step of separating is set at not less than 3.0 vol % nor more than 5.0 vol %.

8. The process for producing single-crystal sapphire according to claim 6, wherein in the step of growing, the single-crystal sapphire is grown in a c-axis direction thereof.

9. A process for producing single-crystal sapphire including pulling up single-crystal sapphire from a melt of aluminum oxide within a crucible, the process comprising the steps of:
growing the single-crystal sapphire by pulling up the single-crystal sapphire from the melt in an atmosphere having an oxygen concentration set at a first concentration; and
separating the single-crystal sapphire from the melt by further pulling up the single-crystal sapphire to pull away from the melt in an atmosphere having an oxygen concentration set at a second concentration that is higher than the first concentration.

10. The process for producing single-crystal sapphire according to claim 9, wherein the second concentration in the step of separating is set at not less than 1.0 vol % nor more than 5.0 vol %.

11. The process for producing single-crystal sapphire according to claim 9, wherein the first concentration in the step of growing is set at not less than 0.6 vol % nor more than 3.0 vol %.
